(19) United States
(12) Patent Application Publication
(10) Pub. No.: US 2019/0018088 A1
(43) Pub. Date: Jan. 17, 2019

(54) MAGNETO-OPTICAL DEFECT CENTER SENSOR INCLUDING LIGHT PIPE WITH FOCUSING LENS

(71) Applicant: LOCKHEED MARTIN CORPORATION, Bethesda, MD (US)

(72) Inventors: Yongdan HU, Bethesda, MD (US); Joseph W. HAHN, Bethesda, MD (US); Gregory Scott BRUCE, Bethesda, MD (US)

(73) Assignee: LOCKHEED MARTIN CORPORATION, Bethesda, MD (US)

(21) Appl. No.: 16/032,054

(22) Filed: Jul. 10, 2018

Related U.S. Application Data
(60) Provisional application No. 62/531,347, filed on Jul. 11, 2017.

(51) Int. Cl. G01R 33/32; G01R 33/26

(52) U.S. Cl. CPC G01R 33/323; G01R 33/26

(57) ABSTRACT

Systems for a magneto-optical defect center material magnetic sensor system that uses fluorescence intensity to distinguish the mₛ=±1 states, and to measure the magnetic field based on the energy difference between the mₛ=+1 state and the mₛ=−1 state, as manifested by the RF frequencies corresponding to each state in some embodiments. The system may include an optical excitation source, which directs optical excitation to the material. The system may further include an RF excitation source, which provides RF radiation to the material. Light from the material may be directed through a light pipe to an optical detector. Light from the material may be directed through an optical filter and a lens to be focused at a focal point corresponding to a collection portion of an optical detector.

### CROSS-REFERENCE TO RELATED APPLICATIONS

The application claims the benefit of and priority to U.S. Provisional Application No. 62/531,347 filed on Jul. 11, 2017, the contents of which are incorporated by reference herein.

### FIELD

The present disclosure generally relates to magneto-optical defect center sensor systems, and more particularly, to magnetic sensor systems including a nitrogen vacancy diamond material.

### BACKGROUND

A number of industrial applications, as well as scientific areas such as physics and chemistry can benefit from magnetic detection and imaging with a device that has extraordinary sensitivity, ability to capture signals that fluctuate very rapidly (bandwidth) all with a substantive package that is extraordinarily small in size and efficient in power. Many advanced magnetic imaging systems can operate in restricted conditions, for example, high vacuum and/or cryogenic temperatures, which can make them inapplicable for imaging applications that require ambient or other conditions. Furthermore, small size, weight and power (SWAP) magnetic sensors of moderate sensitivity, vector accuracy, and bandwidth are valuable in many applications.

### SUMMARY

According to certain embodiments, a system for magnetic detection may include a magneto-optical defect center material comprising magneto-optical defect centers, a radio frequency (RF) excitation source configured to provide RF excitation to the magneto-optical defect center material, an optical detector configured to receive an optical signal emitted by the magneto-optical defect center material, an optical light source, and a light collection assembly. The light collection assembly may include a light pipe, an optical filter, and lens. The light collection assembly may be configured to transmit light emitted from the magneto-optical defect center material to the optical detector.

In some implementations, the optical filter can be a red filter or green filter. In some implementations, the lens can focus light from the light pipe to a focal point corresponding to a position of a collection portion of the optical detector. In some implementations, the optical filter can be integrated into the lens or can be a coating on the light pipe. In some implementations, the light pipe can be a hollow tube or a solid glass member. In some implementations, the lens can be integrated into the light pipe. In some implementations, the light pipe has a first end proximate the magneto-optical defect center material and a second end proximate the lens.

According to at least one other embodiment, a system for magnetic detection may include a magneto-optical defect center material comprising magneto-optical defect centers, a radio frequency (RF) excitation source configured to provide RF excitation to the magneto-optical defect center material, a first and second optical detectors configured to receive optical signals emitted by the magneto-optical defect center material, an optical light source, a first light collection assembly and a second light collection assembly. The first light collection assembly may include a first light pipe, a first optical filter, and a first lens. The first light collection assembly may be configured to transmit light of a first type emitted from the magneto-optical defect center material to the first optical detector. The second light collection assembly may include a second light pipe, a second optical filter, and a second lens. The second light collection assembly may be configured to transmit light of a second type emitted from the magneto-optical defect center material to the second optical detector.

In some implementations, the light of the first type can be a red light and the first optical filter can a red filter. The light of the second type can be a green light and the second optical filter can be a green filter. In some implementations, the first lens can focus light from the first light pipe to a first focal point corresponding to a first position of a first collection portion of the first optical detector, and the second lens can focus light from the second light pipe to a second focal point corresponding to a second position of a second collection portion of the second optical detector. In some implementations, the first optical filter can be integrated into the first lens or the second optical filter can be integrated into the second lens. The first optical filter can be a coating on the first light pipe or the second optical filter can be a coating on the second light pipe. In some implementations, at least one of the first light pipe and the second light pipe can include a hollow tube. At least one of the first light pipe and the second light pipe can include a solid glass member. In some implementations, the first lens can be integrated into the first light pipe or the second lens can be integrated into the second light pipe.

According to at least one other embodiment, a method for magnetic detection can include providing, by a radio frequency (RF) excitation source, RF excitation to a magneto-optical defect center material. The magneto-optical defect center material can include magneto-optical defect centers. The method can include emitting, by an optical light source, a first light towards the magneto-optical defect center material. The method can include receiving, by a light collection assembly, an optical signal emitted by the magneto-optical defect center material responsive to the light emitted by the optical light source. The method can include transmitting, by the light collection assembly, the optical signal emitted from the magneto-optical defect center material to an optical detector. The method can include receiving, by the optical detector, the optical signal.

According to at least one other embodiment, a system for magnetic detection may include a magneto-optical defect center material comprising magneto-optical defect centers, radio frequency (RF) excitation means for providing RF excitation to the magneto-optical defect center material, optical detection means for receiving an optical signal emitted by the magneto-optical defect center material, optical light excitation means, and light collection means for transmitting light emitted from the magneto-optical defect center material to the optical detection means.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 illustrates an orientation of an NV center in a diamond lattice;

FIG. 2 illustrates an energy level diagram showing energy levels of spin states for the NV center;

FIG. 3 illustrates a schematic diagram of a magneto-optical defect center sensor system;

FIG. 4 is a graph illustrating the fluorescence as a function of an applied RF frequency of a magneto-optical defect center along a given direction for a zero magnetic field, and also for a non-zero magnetic field having a component along the defect center axis;

FIG. 5 is a graph illustrating the fluorescence as a function of an applied RF frequency for four different magneto-optical defect center orientations for a non-zero magnetic field;

FIG. 6 is a graphical diagram illustrating a Ramsey pulse sequence;

FIG. 7 is a partial cross-sectional view illustrating a magneto-optical defect center sensor and showing assemblies for light pipes and lenses for green and red light collection;

FIG. 8 is a cross-section illustrating a hollow light pipe with a collection lens and an associated mount for red light collection;

FIG. 9 is a cross-section illustrating a hexagonal light pipe with a collection lens and an associated mount for red light collection; and

FIG. 10 is a cross-section illustrating a light pipe with a collection lens and an associated mount for green light collection.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

Following below are more detailed descriptions of various concepts related to, and implementations of, methods, apparatuses, and systems for light pipes having focusing lensing.

A light pipe with a lens at the end of the light pipe provides a collection system that efficiently starts and ends the process of directing and focusing the light to the photo diode. The light pipe efficiently collects a large amount of light from the light source and then directs that light to a lens or system of lenses which then efficiently focus the light onto the collection surface of the photo diode such that the maximum amount of light is collected and measured. Since the sensitivity of an optical defect based magnetometer is directly related to the efficiency of the light collection, the combination of a light pipe with a lens or lenses results in a direct sensitivity improvement for the magnetometer system.

Atomic-sized magneto-optical defect centers, such as nitrogen-vacancy (NV) centers in diamond lattices, have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. Magneto-optical defect center sensors, such as a diamond nitrogen vacancy (DNV) sensor, can be maintained in room temperature and atmospheric pressure and can be even used in liquid environments. For a DNV sensor, a green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with mₛ=−1, 0, +1) of the NV centers to split in relation to an external magnetic field projected along the NV axis, resulting in two spin resonance frequencies. The difference between the two spin resonance frequencies can correlate to a measure of the strength of the external magnetic field. A photo detector can measure the fluorescence (red light) emitted by the optically excited NV centers.

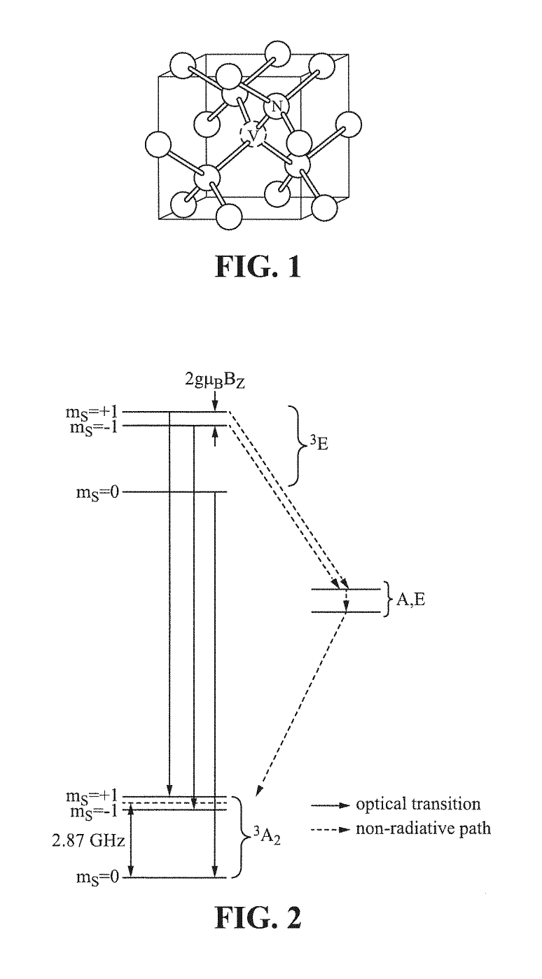

Nitrogen-vacancy centers (NV centers) are defects in a diamond's crystal structure, which can purposefully be manufactured in synthetic diamonds as shown in FIG. 1. In general, when excited by green light and microwave radiation, the NV centers cause the diamond to generate red light. When excited with green light, the NV defect centers generate red light fluorescence. After sufficient time (on order of nanoseconds to microseconds) the fluorescence counts stabilize. When microwave radiation is added, the NV electron spin states are changed, and this results in a change in intensity of the red fluorescence. The changes in fluorescence may be recorded as a measure of electron spin resonance. By measuring the changes, the NV centers may be used to accurately detect the magnetic field strength.

The NV center may exist in a neutral charge state or a negative charge state. Conventionally, the neutral charge state uses the nomenclature NV⁰, while the negative charge state uses the nomenclature NV, which is adopted in this description.

The NV center may have a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry and, as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing the external magnetic field with the component along the NV axis lifts the degeneracy of the mₛ=±1 energy levels, splitting the energy levels mₛ=±1 by an amount 2 gμ_{B}B_{z}, where g is the Lande g-factor, μ_{B} is the Bohr magneton, and B_{z} is the component of the external magnetic field along the NV axis. This relationship is correct to a first order and inclusion of higher order corrections is a straightforward matter.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A_{z} may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

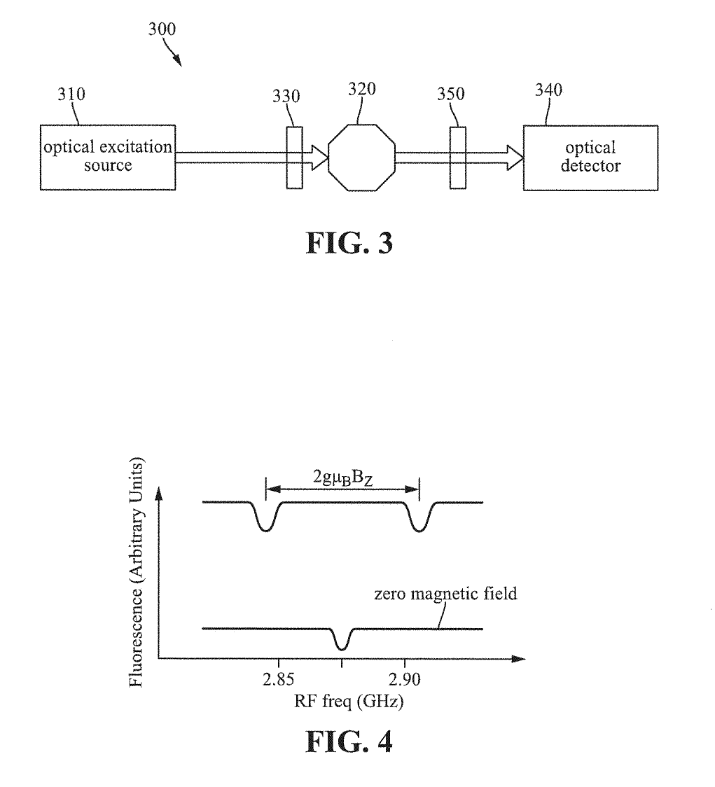

FIG. 3 is a schematic diagram illustrating a magneto-optical defect center sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300 includes an optical excitation source 310, which directs optical excitation to a magneto-optical defect center material 320 with magneto-optical defect centers. The system further includes an RF excitation source 330, which provides RF radiation to the magneto-optical defect center material 320. Light from the magneto-optical defect center material may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the magneto-optical defect center material 320 is directed through the optical filter 350 to filter out light in the excitation band (in the green, for example), and to pass light in the red fluorescence band, which in turn is detected by the detector 340. The optical excitation light source 310, in addition to exciting fluorescence in the magneto-optical defect center material 320, also serves to reset the population of the mₛ=0 spin state of the ground state ³A₂ to a maximum polarization, or other desired polarization.

For continuous wave excitation, the optical excitation source 310 continuously pumps the magneto-optical defect centers, and the RF excitation source 330 sweeps across a frequency range, which includes the zero splitting (when the mₛ=±1 spin states have the same energy) photon energy of approximately 2.87 GHz for NV centers. The fluorescence for an RF sweep corresponding to a magneto-optical defect center material 320 with magneto-optical defect centers aligned along a single direction is shown in FIG. 4 for different magnetic field components B_{z} along the magneto-optical defect axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence (described in more detail below), spin echo pulse sequence, etc.

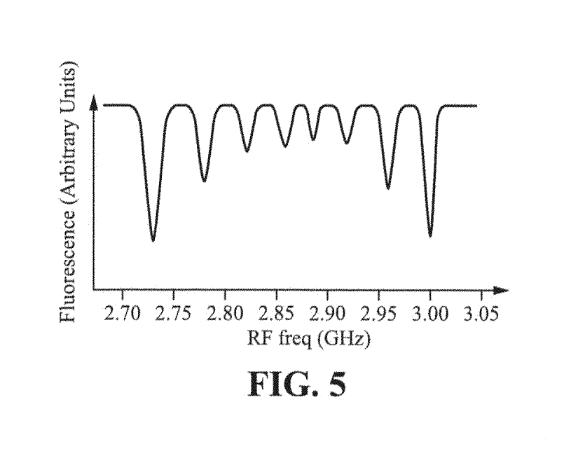

In general, the magneto-optical defect center material 320 will have magneto-optical defect centers aligned along directions of four different orientation classes. FIG. 5 illustrates fluorescence as a function of RF frequency for the case where the magneto-optical defect center material 320 has magneto-optical defect centers aligned along directions of four different orientation classes. In this case, the component B_{z} along each of the different orientations may be determined. These results, along with the known orientation of crystallographic planes of a magneto-optical defect material lattice, allow not only the magnitude of the external magnetic field to be determined, but also the direction of the magnetic field.

While FIG. 3 illustrates a magneto-optical defect center sensor system 300 with a magneto-optical defect center material 320 having a plurality of magneto-optical defect centers, such as a DNV material with NV centers. In general, the magnetic sensor system may instead employ a different magneto-optical defect center material with a plurality of magneto-optical defect centers. Magneto-optical defect center materials include but are not be limited to diamonds, Silicon Carbide (SiC), Phosphorous, and other materials with nitrogen, boron, carbon, silicon, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with magneto-optical defect center material.

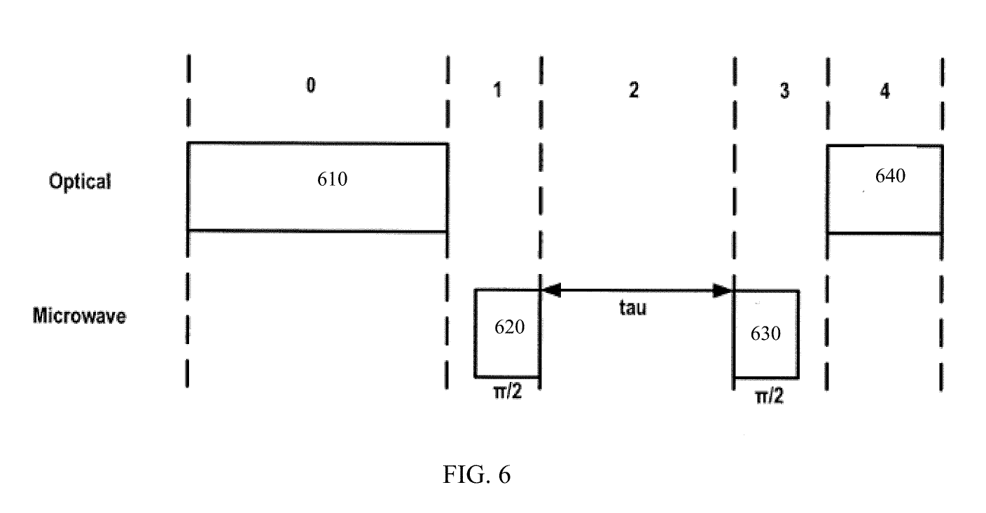

A Ramsey pulse sequence is a pulsed RF laser scheme that is believed to measure the free precession of the magnetic moment in the magneto-optical defect center material 320 with magneto-optical defect centers, and is a technique that quantum mechanically prepares and samples the electron spin state. FIG. 6 is an example of a schematic diagram illustrating the Ramsey pulse sequence. As shown in FIG. 6, a Ramsey pulse sequence includes optical excitation pulses and RF excitation pulses over a five-step period. In a first step, during a period 0, a first optical excitation pulse 610 is applied to the system to optically pump electrons into the ground state (i.e., mₛ=0 spin state). This is followed by a first RF excitation pulse 620 (in the form of, for example, a microwave (MW) π/2 pulse) during a period 1. The first RF excitation pulse 620 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 630 (in the form of, for example, a MW π/2 pulse) is applied during a period 3 to project the system back to the mₛ=0 and mₛ=+1 basis. Finally, during a period 4, a second optical pulse 640 is applied to optically sample the system and a measurement basis is obtained by detecting the fluorescence intensity of the system. The RF excitation pulses applied are provided at a given RF frequency in relation to the Lorentzians such as referenced in connection with FIG. 5.

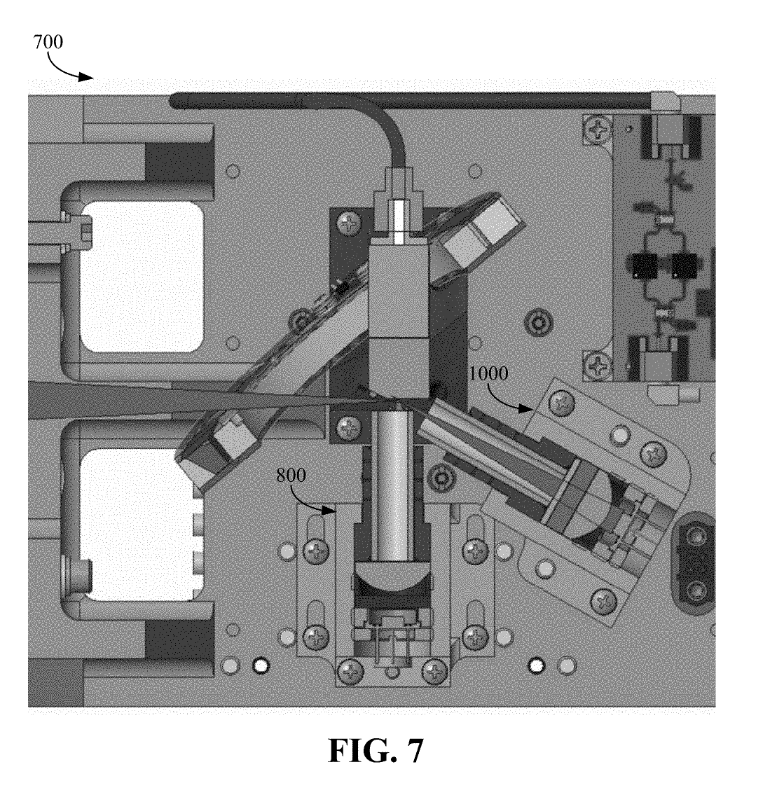

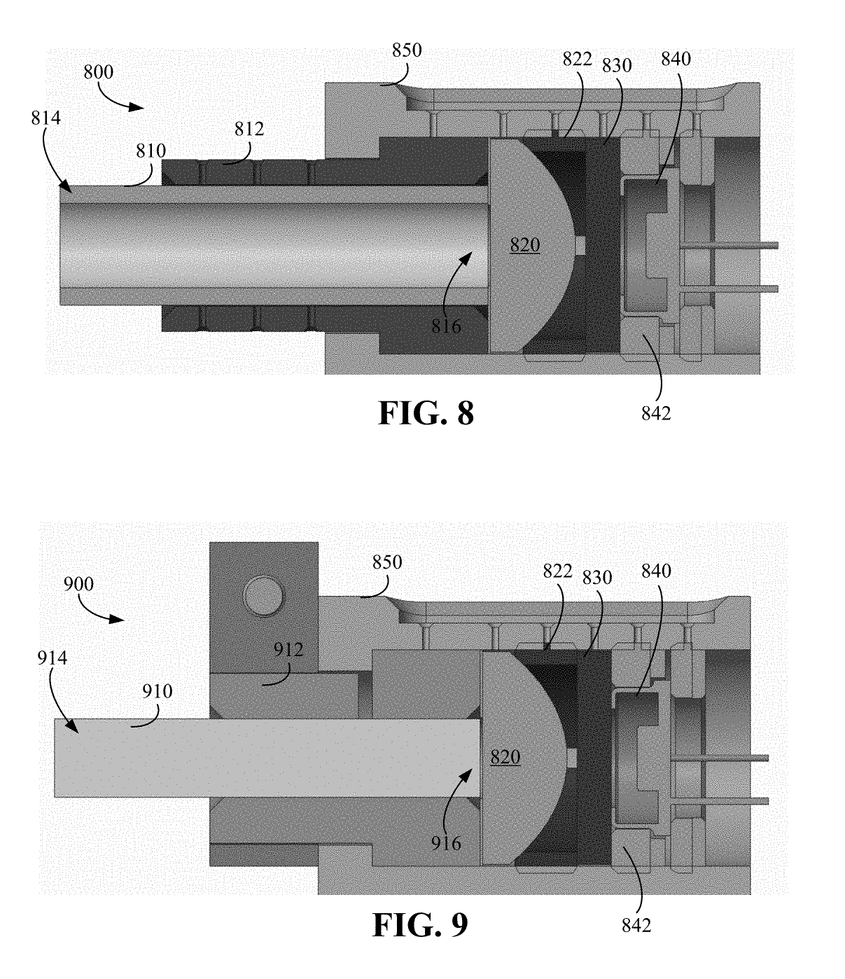

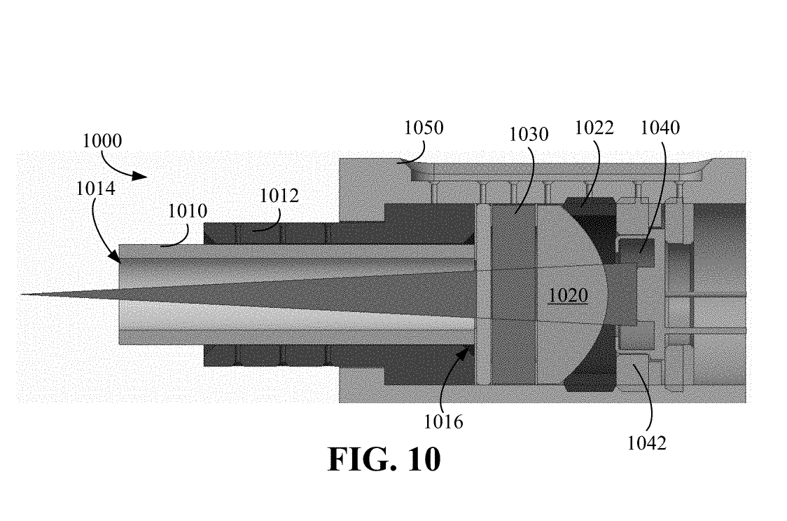

FIG. 7 is partial cross-sectional view illustrating some implementations of a magneto-optical defect center sensor 700 and showing assemblies 800, 1000 for light pipes and lenses for green and red light collection. Green light is emitted from a laser optical assembly (not shown) and focused on a magneto-optical defect center material, such as a diamond having nitrogen vacancies. The red light collection assembly 800 is positioned relative to the magneto-optical defect center material to collect the red light emitted. The red light collection assembly 800 is described in greater detail below in reference to FIG. 8. The green light collection assembly 1000 is positioned relative to the magneto-optical defect center material to collect the green light that passes through the magneto-optical defect center material. In the implementation shown, the green light collection assembly 1000 is offset at an angle of approximately 29.25 degrees based on the geometric configuration of the magneto-optical defect center material. The green light collection assembly 1000 is described in greater detail below in reference to FIG. 10.

FIG. 8 depicts some implementations of a red light collection assembly 800. The red light collection assembly 800 may include an optical light pipe 810, a light pipe mount 812, a lens 820, a lens retention ring 822, a red filter 830, a photo diode 840, a photo diode mount 842, and an assembly mount 850. The optical light pipe 810 may be a hollow copper tube having a highly reflective interior surface to reflect the light within the light pipe 810. The air within the hollow tube may be substantially lossless for optical transmission. In some implementations, the reflective interior surface can be a silver layer. In other implementations, the reflective interior surface can be configured to minimize optical losses at a specific wavelength, such as 650 nanometers (nm) to 850 nm. In other implementations, the inner surface of the light pipe 810 can incorporate an optical filtering coating to absorb or filter wavelengths of light that are not of interest. In some instances, the light pipe 810 may have a 5 millimeter (mm) inner diameter, a 7 mm outer diameter, and be 25 mm in length. The light pipe 810 may be coupled or staked to the light pipe mount 812 via adhesive within one or more openings formed in the light pipe mount 812. The light pipe mount 812 may be secured within the assembly mount 850 via adhesive within one or more openings formed in the assembly mount 850. The light pipe 810 may be positioned proximate the magneto-optical defect center material at a first end 814, such as directly adjacent such that the first end 814 is coplanar with a plane of the magneto-optical defect center material, and may be positioned proximate the lens 820 at a second end 816. Because of the lens 820 that can focus light transmitted through the light pipe to a focal point and/or collection portion of the photo diode 840, the light pipe 810 can be large in diameter relative to a light emitting face of the magneto-optical defect center material. Thus, substantially all of the light emitted by the magneto-optical defect center material can be captured by the light pipe 810 and transmitted toward the lens 820. In some implementation, a spacer washer can be positioned between the second end 816 and the lens 820.

The lens 820 may be an aspheric lens or the like positioned to focus the light exiting the light pipe 810 from the second end 816 to a focal point corresponding to a collection portion of the photo diode 840. In some implementations, the lens 820 can be a plano-convex lens having a planar side adjacent the second end 816 of the light pipe to maintain transference and a convex side facing the photo diode 840 for focusing to a focal point. In still other implementations, the lens 820 can be a Fresnel lens or any other focusing lens. By positioning the lens 820 directly downstream of the light pipe 810, substantially all of the light exiting the light pipe 810 may be collected by the photo diode 840. A lens retention ring 822 mechanically secures the lens 820 in position within the assembly mount 850. In addition, the lens 820 and lens retention ring 822 can also be secured within the assembly mount 850 via adhesive within one or more openings formed in the assembly mount 850. In some implementations, the lens 820 may be positioned within the light pipe 810 and/or may be integrally formed with the light pipe 810.

A red filter 830 may be positioned proximate the lens 820 to filter out wavelengths of light that do not correspond to a wavelength of interest, such as 650 nm to 850 nm. In some implementations, the red filter 830 may be a coating on the lens 820 and/or may be incorporated integrally into the lens 820 itself. The red filter 830 can also be secured within the assembly mount 850 via adhesive within one or more openings formed in the assembly mount 850.

A photo diode 840 may be positioned such that the collection portion may be located at the focal point of the lens 820. The photo diode 840 can be coupled to a photo diode mount 842 to center the photo diode 840 within the assembly mount 850. In some implementations, the photo diode mount 842 can also be secured within the assembly mount 850 via adhesive within one or more openings formed in the assembly mount 850. In some implementations, a retaining ring can be used to axially secure the photo diode mount 842 within the assembly mount 850.

FIG. 9 depicts another red light collection assembly 900 that may include an optical light pipe 910, a light pipe mount 912, a lens 820, a lens retention ring 822, a red filter 830, a photo diode 840, a photo diode mount 842, and the assembly mount 850. The optical light pipe 910 may be a solid glass pipe having a highly reflective coating to reflect the light within the light pipe 910. In some implementations, the reflective coating can be configured to minimize optical losses at a specific wavelength, such as 650 nm to 850 nm. In other implementations, the light pipe 910 itself can incorporate an optical filtering material to absorb or filter wavelengths of light that are not of interest. In some instances, the light pipe 910 may be a hexagonal solid borosilicate glass material. The light pipe 910 may be coupled to the light pipe mount 912 via a compressible portion of the light pipe mount 912 that may be clamped down to secure the light pipe 910 to the light pipe mount 912. The light pipe mount 912 can be secured within the assembly mount 850 via adhesive within one or more openings formed in the assembly mount 850. The light pipe 910 may be positioned proximate the magneto-optical defect center material at a first end 914, such as directly adjacent such that the first end 914 is coplanar with a plane of the magneto-optical defect center material, and may be positioned proximate a lens 820 at a second end 916. Because of the lens 820 that can focus light transmitted through the light pipe to a focal point and/or collection portion of the photo diode 840, the light pipe 910 can be large in diameter relative to a light emitting face of the magneto-optical defect center material. Thus, substantially all of the light emitted by the magneto-optical defect center material can be captured by the light pipe 910 and transmitted to toward the lens 820. In some implementation, a spacer washer can be positioned between the second end 916 and the lens 820.

FIG. 10 depicts some implementations of a green light collection assembly 1000. The green light collection assembly 1000 includes an optical light pipe 1010, a light pipe mount 1012, a green filter 1030, a lens 1020, a lens retention ring 1022, a photo diode 1040, a photo diode mount 1042, and the assembly mount 1050. The optical light pipe 1010 may be a hollow copper tube having a highly reflective interior surface to reflect the light within the light pipe 1010. The air within the hollow tube may be substantially lossless for optical transmission. In some implementations, the reflective interior surface can be a silver layer. In other implementations, the reflective interior surface can be configured to minimize optical losses at a specific wavelength, such as 500 nm to 550 nm. In other implementations, the inner surface of the light pipe 1010 can incorporate an optical filtering coating to absorb or filter wavelengths of light that are not of interest. In some instances, the light pipe 1010 may have a 5 millimeter (mm) inner diameter, a 7 mm outer diameter, and be 25 mm in length. The light pipe 1010 may be coupled or staked to the light pipe mount 1012 via adhesive within one or more openings formed in the light pipe mount 1012. The light pipe mount 1012 may be secured within the assembly mount 1050 via adhesive within one or more openings formed in the assembly mount 1050. The light pipe 1010 may be positioned proximate the magneto-optical defect center material at a first end 1014, such as directly adjacent such that the first end 1014 is coplanar with a plane of the magneto-optical defect center material, and is positioned proximate a green filter 1030 at a second end 1016. Because of the lens 1020 that can focus light transmitted through the light pipe to a focal point and/or collection portion of the photo diode 1040, the light pipe 1010 can be large in diameter relative to a light emitting face of the magneto-optical defect center material. Thus, substantially all of the light emitted by the magneto-optical defect center material can be captured by the light pipe 1010 and transmitted to toward the lens 1020. In some implementation, a spacer washer can be positioned between the second end 1016 and the green filter 1030.

A green filter 1030 is positioned proximate the lens 1020 to filter out wavelengths of light that do not correspond to a wavelength of interest, such as 500 nm to 550 nm. In some implementations, multiple green filters 1030 may be used depending on the intensity of light. In some implementations, the green filter 1030 may be a coating on the lens 1020 and/or may be incorporated integrally into the lens 1020 itself. The green filter 1030 can also be secured within the assembly mount 1050 via adhesive within one or more openings formed in the assembly mount 1050.

The lens 1020 may be an aspheric lens or the like positioned to focus the light exiting the light pipe 1010 to a focal point corresponding to a collection portion of the photo diode 1040. In some implementations, the lens 1020 can be a plano-convex lens having a planar side adjacent the second end 1016 of the light pipe to maintain transference and a convex side facing the photo diode 1040 for focusing to a focal point. In still other implementations, the lens 1020 can be a Fresnel lens or any other focusing lens. Thus, by positioning the lens 1020 downstream of the light pipe 1010, substantially all of the light exiting the light pipe 1010 may be collected by the photo diode 1040. A lens retention ring 1022 mechanically secures the lens 1020 in position within the assembly mount 1050. In addition, the lens 1020 and lens retention ring 1022 can also be secured within the assembly mount 1050 via adhesive within one or more openings formed in the assembly mount 1050. In some implementations, the lens 1020 may be positioned within the light pipe 1010 and/or may be integrally formed with the light pipe 1010.

A photo diode 1040 may be positioned such that the collection portion is located at the focal point of the lens 1020. The photo diode 1040 can be coupled to a photo diode mount 1042 to center the photo diode 1040 within the assembly mount 1050. In some implementations, the photo diode mount 1042 can also be secured within the assembly mount 1050 via adhesive within one or more openings formed in the assembly mount 1050. In some implementations, a retaining ring can be used to axially secure the photo diode mount 1042 within the assembly mount 1050.

When an optical excitation source, such as a green wavelength laser, is directed toward the magneto-optical defect center material, the magneto-optical defect centers fluoresce and emit a different wavelength of light. The light pipes 810, 910, 1010 of the light collection assemblies 800, 900, 1000 described herein can be sized to be larger than an emitting surface of the magneto-optical defect center material and/or the magneto-optical defect center material itself. For instance, the diameters of the light pipes 810, 910, 1010 can be two, three, four, five, ten, fifteen, twenty, thirty, forty, fifty, one hundred, two hundred, three hundred, four hundred, five hundred times the width or length of the emitting surface of the magneto-optical defect center material and/or the magneto-optical defect center material itself. Thus, the light pipes 810, 910 can be positioned adjacent or otherwise proximate to the emitting surface of the magneto-optical defect center material to capture substantially all emitted fluorescence. Similarly, the light pipe 1010 can be positioned adjacent or otherwise proximate to the magneto-optical defect center material to capture substantially all passed through optical excitation light. The lenses 820, 1020 focus the captured fluorescence or passed through optical excitation light from the end of the light pipe 810, 910, 1010 to a focal point of collection portion of the photo diodes 840, 1040 such that minimal fluorescence or passed through optical excitation light is lost.

In some implementations, the filters and lenses described herein can be incorporated into a customized photo diode to integrate the components into a compact package.

The description is provided to enable any person skilled in the art to practice the various embodiments described herein. While some embodiments have been particularly described with reference to the various figures and configurations, it should be understood that these are for illustration purposes only and should not be taken as limiting the scope of the subject technology.

There may be many other ways to implement. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made by one having ordinary skill in the art, without departing from the scope of the subject technology.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A system for magnetic detection, comprising:
a magneto-optical defect center material comprising magneto-optical defect centers;
a radio frequency (RF) excitation source configured to provide RF excitation to the magneto-optical defect center material;
an optical detector configured to receive an optical signal emitted by the magneto-optical defect center material;
an optical light source; and
a light collection assembly comprising a light pipe, an optical filter, and a lens, wherein the light collection assembly is configured to transmit light emitted from the magneto-optical defect center material to the optical detector.

2. The system of claim 1, wherein the optical filter is a red filter.

3. The system of claim 1, wherein the optical filter is a green filter.

4. The system of claim 1, wherein the lens focuses light from the light pipe to a focal point corresponding to a position of a collection portion of the optical detector.

5. The system of claim 1, wherein the optical filter is integrated into the lens.

6. The system of claim 1, wherein the optical filter is a coating on the light pipe.

7. The system of claim 1, wherein the light pipe is a hollow tube.

8. The system of claim 1, wherein the light pipe is a solid glass member.

9. The system of claim 1, wherein the lens is integrated into the light pipe.

10. The system of claim 1, wherein the light pipe has a first end proximate the magneto-optical defect center material and a second end proximate the lens.

11. A system for magnetic detection, comprising:
a magneto-optical defect center material comprising magneto-optical defect centers;
a radio frequency (RF) excitation source configured to provide RF excitation to the magneto-optical defect center material;
a first optical detector and a second optical detector configured to receive optical signals emitted by the magneto-optical defect center material;
an optical light source;
a first light collection assembly comprising a first light pipe, a first optical filter, and a first lens, wherein the first light collection assembly is configured to transmit light of a first type emitted from the magneto-optical defect center material to the first optical detector; and
a second light collection assembly comprising a second light pipe, a second optical filter, and a second lens, wherein the second light collection assembly is configured to transmit light of a second type emitted from the magneto-optical defect center material to the second optical detector.

12. The system of claim 11, wherein the light of the first type is a red light and the first optical filter is a red filter.

13. The system of claim 11, wherein the light of the second type is a green light and the second optical filter is a green filter.

14. The system of claim 11, wherein the first lens focuses light from the first light pipe to a first focal point corresponding to a first position of a first collection portion of the first optical detector and the second lens focuses light from the second light pipe to a second focal point corresponding to a second position of a second collection portion of the second optical detector.

15. The system of claim 11, wherein the first optical filter is integrated into the first lens or the second optical filter is integrated into the second lens.

16. The system of claim 11, wherein the first optical filter is a coating on the first light pipe or the second optical filter is a coating on the second light pipe.

17. The system of claim 11, wherein at least one of the first light pipe and the second light pipe includes a hollow tube.

18. The system of claim 11, wherein at least one of the first light pipe and the second light pipe includes a solid glass member.

19. The system of claim 11, wherein the first lens is integrated into the first light pipe or the second lens is integrated into the second light pipe.

20. A method for magnetic detection, comprising:
providing, by a radio frequency (RF) excitation source, RF excitation to a magneto-optical defect center material, the magneto-optical defect center material including magneto-optical defect centers;
emitting, by an optical light source, a first light towards the magneto-optical defect center material;
receiving, by a light collection assembly, an optical signal emitted by the magneto-optical defect center material responsive to the light emitted by the optical light source;
transmitting, by the light collection assembly, the optical signal emitted from the magneto-optical defect center material to an optical detector; and
receiving, by the optical detector, the optical signal.

21. A system for magnetic detection, comprising:
a magneto-optical defect center material comprising magneto-optical defect centers;
radio frequency (RF) excitation means for providing RF excitation to the magneto-optical defect center material;
optical detection means for receiving an optical signal emitted by the magneto-optical defect center material;
optical light excitation means; and
light collection means for transmitting light emitted from the magneto-optical defect center material to the optical detection means.
